(19) United States
(12) Patent Application Publication
(10) Pub. No.: US 2026/0213079 A1
(43) Pub. Date: Jul. 23, 2026

(54) CAPACITOR COMPONENT AND INTEGRATED CIRCUIT CHIP PACKAGE INCLUDING SAME

(71) Applicant: POINT ENGINEERING CO., LTD., Asan-Si (KR)

(72) Inventors: Bum Mo AHN, Suwon-Si (KR); Seung Ho PARK, Hwaseong-Si (KR); Tae Hwan SONG, Yongin-Si (KR)

(73) Assignee: POINT ENGINEERING CO., LTD., Asan-Si (KR)

(21) Appl. No.: 19/137,047

(22) PCT Filed: Dec. 5, 2023
(86) PCT No.: PCT/KR2023/019903

§ 371 Date: Jun. 9, 2025

(30) Foreign Application Priority Data
Dec. 9, 2022 (KR) 10-2022-0171798

(51) Int. Cl. H01G 4/33; H01G 4/005; H10D 1/00; H10D 1/68

(52) U.S. Cl. CPC H01G 4/33; H01G 4/005; H10D 1/042; H10D 1/714; H10D 1/716

(57) ABSTRACT

The present invention provides a high-capacitance capacitor component and an integrated circuit chip package including same, the component comprising: an anodic oxide film body including a plurality of pores; a first electrode layer including a first surface electrode part formed on the surface of the body and a first pore electrode part formed on the inner wall of the pore; a dielectric layer including a surface dielectric part formed on the first surface electrode part and a pore dielectric part formed on the first pore electrode part; and a second electrode layer including a second surface electrode part formed on the surface dielectric part and a second pore electrode part formed on the pore dielectric part.

### CROSS-REFERENCE TO RELATED APPLICATION

This application is a 371 of international application of PCT application serial no. PCT/KR2023/019903, filed on Dec. 5, 2023, which claims the priority benefit of Korea application no. 10-2022-0171798, filed on Dec. 9, 2022. The entirety of each of the above mentioned patent applications is hereby incorporated by reference herein and made a part of this specification.

### TECHNICAL FIELD

The present invention relates to a capacitor component and an integrated circuit chip package comprising the same.

### BACKGROUND

A multilayer ceramic capacitor (MLCC), which is one type of multilayer chip electronic component, is used in various electronic devices due to its advantages of being compact, ensuring high capacity, and being easy to mount. The multilayer ceramic capacitor has a structure in which a plurality of dielectric layers and internal electrodes of different polarities are alternately arranged between the dielectric layers. Recently, as electronic devices tend to become smaller, multilayer ceramic capacitors are also following the trend of miniaturization. To achieve miniaturization, high-capacity multilayer ceramic capacitors are being implemented by thinning the dielectric layers and increasing the number of stacked internal electrodes.

The multilayer ceramic capacitor comprises a plurality of dielectric layers and first and second internal electrodes formed on the dielectric layers. A plurality of dielectric layers with internal electrodes formed thereon are stacked, and the first and second internal electrodes are arranged to face each other with one dielectric layer interposed therebetween.

However, such capacitors have limitations in increasing capacitance because the internal electrodes are in a two-dimensional planar form.

### PRIOR ART DOCUMENTS

### Patent Documents

(Patent Document 1) Registration Number 10-2192426, Registered Patent Gazette

(Patent Document 2) Registration Number 10-2189805, Registered Patent Gazette

### DISCLOSURE

### Technical Problem

Accordingly, the present invention has been devised to solve the problems of the prior art described above, and an object of the present invention is to provide a high-capacity capacitor component and an integrated circuit chip package comprising the same.

### Means for Solving the Problem

To achieve the above-described object, a capacitor component according to the present invention comprises: an anodized membrane body having a plurality of pores; a first electrode layer comprising a first surface electrode part formed on a surface of the anodized membrane body and a first pore electrode part formed on an inner wall of the pores; a dielectric layer comprising a surface dielectric part formed on the first surface electrode part and a pore dielectric part formed on the first pore electrode part; and a second electrode layer comprising a second surface electrode part formed on the surface dielectric part and a second pore electrode part formed on the pore dielectric part.

In addition, the first pore electrode part is formed only on a portion of the inner wall of the pores.

In addition, the first pore electrode part is formed on the entire inner wall of the pores.

In addition, inside the pores, a depth of the pore dielectric part is shallower than a depth of the first pore electrode part and deeper than a depth of the second pore electrode part.

Meanwhile, a capacitor component according to the present invention comprises: an anodized membrane body having a plurality of pores; a first upper electrode layer comprising a first upper surface electrode part formed on an upper surface of the anodized membrane body and a first upper pore electrode part formed on a portion of an upper inner wall of the pores; an upper dielectric layer comprising an upper surface dielectric part formed on the first upper surface electrode part and an upper pore dielectric part formed on the first upper pore electrode part; a second upper electrode layer comprising a second upper surface electrode part formed on the upper surface dielectric part and a second upper pore electrode part formed on the upper pore dielectric part; a first lower electrode layer comprising a first lower surface electrode part formed on a lower surface of the anodized membrane body and a first lower pore electrode part formed on a portion of a lower inner wall of the pores; a lower dielectric layer comprising a lower surface dielectric part formed on the first lower surface electrode part and a lower pore dielectric part formed on the first lower pore electrode part; and a second lower electrode layer comprising a second lower surface electrode part formed on the lower surface dielectric part and a second lower pore electrode part formed on the lower pore dielectric part.

In addition, the first upper pore electrode part and the first lower pore electrode part are spaced apart from each other.

In addition, the upper pore dielectric part and the lower pore dielectric part are spaced apart from each other.

In addition, the second upper pore electrode part and the second lower pore electrode part are spaced apart from each other.

Meanwhile, an integrated circuit chip package according to the present invention comprises: a package substrate; a semiconductor chip mounted on the package substrate; a molding part protecting the semiconductor chip; and a capacitor component provided inside or on the package substrate, wherein the capacitor component comprises: an anodized membrane body having a plurality of pores; a first electrode layer comprising a first surface electrode part formed on a surface of the anodized membrane body and a first pore electrode part formed on an inner wall of the pores; a dielectric layer comprising a surface dielectric part formed on the first surface electrode part and a pore dielectric part formed on the first pore electrode part; and a second electrode layer comprising a second surface electrode part formed on the surface dielectric part and a second pore electrode part formed on the pore dielectric part.

### Effect of the Invention

The present invention provides a high-capacity capacitor component and an integrated circuit chip package comprising the same.

### BRIEF DESCRIPTION OF DRAWINGS

FIG. 1 is a perspective view including a partially cut portion of a capacitor component according to a preferred first embodiment of the present invention.

FIG. 2 is a cross-sectional view of a capacitor component according to a preferred first embodiment of the present invention.

FIG. 3 is a perspective view of an anodized membrane body.

FIGS. 4A to 4D are drawings for explaining a manufacturing method of a capacitor component according to a preferred first embodiment of the present invention.

FIG. 5 is a cross-sectional view of a capacitor component according to a preferred second embodiment of the present invention.

FIG. 6 is a cross-sectional view of a capacitor component according to a preferred third embodiment of the present invention.

FIG. 7 is a cross-sectional view of a capacitor component according to a preferred fourth embodiment of the present invention.

FIG. 8 is a cross-sectional view of an integrated circuit chip package according to a preferred embodiment of the present invention.

### DETAILED DESCRIPTION OF THE EMBODIMENTS

The following content merely illustrates the principles of the invention. Therefore, those skilled in the art can implement the principles of the invention and invent various devices included in the concept and scope of the invention, even though they are not explicitly described or illustrated in this specification. Furthermore, all conditional terms and embodiments listed in this specification are, in principle, explicitly intended only for the purpose of understanding the concept of the invention and should not be understood as being limited to the specifically listed embodiments and conditions.

The aforementioned objectives, features, and advantages will become more apparent through the following detailed description in connection with the accompanying drawings, thereby enabling those skilled in the art to easily implement the technical idea of the invention.

The embodiments described in this specification will be explained with reference to ideal exemplary cross-sectional views and/or perspective views of the invention. The thicknesses of the films and regions shown in these drawings are exaggerated for effective explanation of the technical content. The shapes in the exemplary drawings may be modified due to manufacturing techniques and/or tolerances. Additionally, the number of molded objects shown in the drawings is illustrative, and only a portion is depicted in the drawings. Therefore, the embodiments of the invention are not limited to the specific forms shown but also include variations in shape generated according to the manufacturing process.

### Capacitor Component 100 According to the First Embodiment

First, a capacitor component 100 according to a preferred first embodiment of the invention will be described.

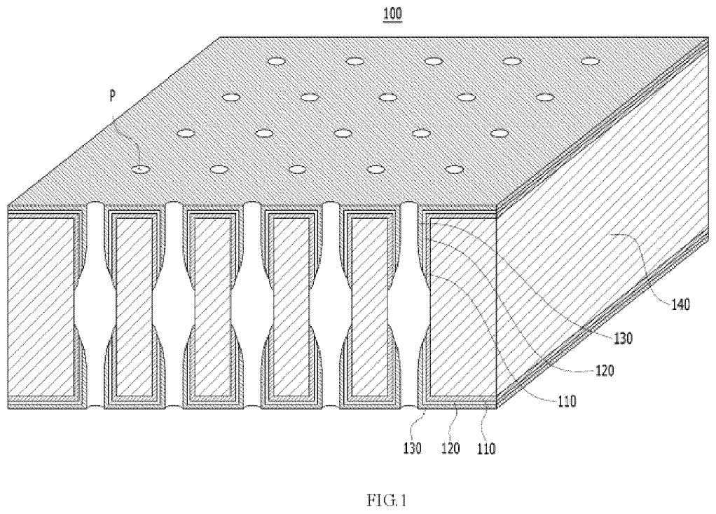

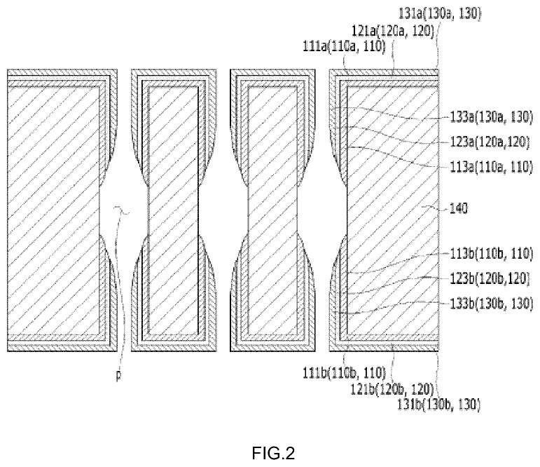

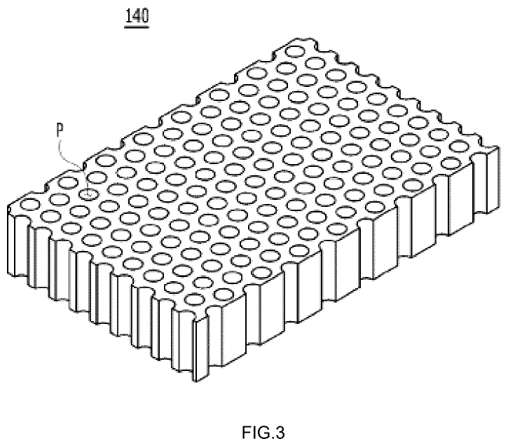

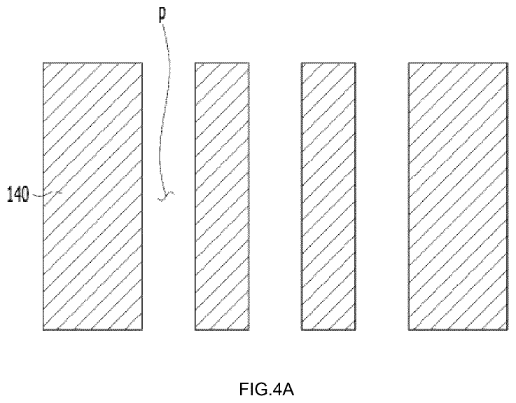

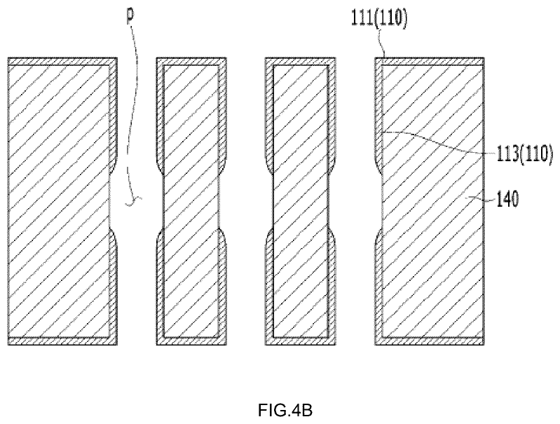

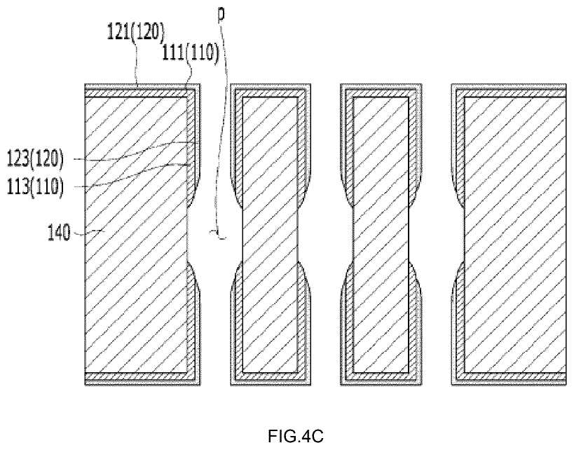

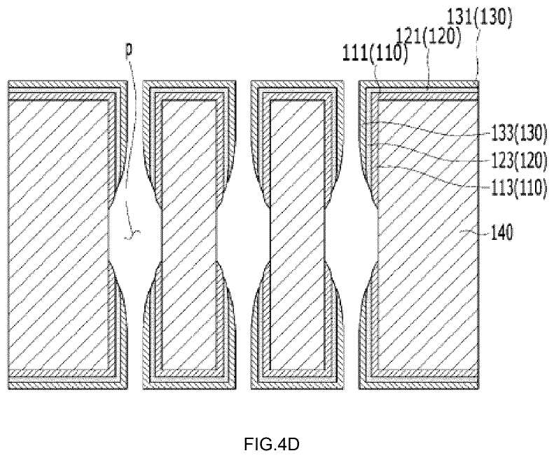

FIG. 1 is a perspective view including a partially cut portion of the capacitor component according to the preferred first embodiment of the invention, FIG. 2 is a cross-sectional view of the capacitor component according to the preferred first embodiment of the invention, FIG. 3 is a perspective view of the anodized membrane body, and FIGS. 4A to 4D are drawings for explaining the manufacturing method of the capacitor component according to the preferred first embodiment of the invention.

Referring to FIGS. 1 and 2, the capacitor component 100 comprises an anodized membrane body 140, a first electrode layer 110, a dielectric layer 120, and a second electrode layer 130.

The anodized membrane body 140 refers to a membrane formed by anodizing a base metal M, and the pores P refer to holes formed during the process of forming the anodized membrane by anodizing the base metal M. For example, when the base metal M is aluminum Al or an aluminum alloy, anodizing the base metal M forms an anodized membrane of aluminum oxide Al₂O₃ material on the surface of the base metal M. However, the base metal M is not limited thereto and may include Ta, Nb, Ti, Zr, Hf, Zn, W, Sb, or their alloys.

After anodizing, when the base metal M is removed, only the anodized membrane body 140 of aluminum oxide Al₂O₃ material remains. Additionally, the barrier layer is removed, and the pores P are opened at the top and bottom. The anodized membrane body 140 comprises a plurality of pores P, and the pores P have a length of 20 μm to 200 μm and a diameter of 10 nm to 1 μm. The pitch between adjacent pores P is 20 nm to 200 nm. The preferred embodiment of the invention significantly improves the capacitance per unit volume of the capacitor component 100 by utilizing these pores P.

The first electrode layer 110 comprises a first surface electrode part 111 formed on the surface of the anodized membrane body 140 and a first pore electrode part 113 formed on the inner wall of the pores P. The first surface electrode part 111 is a portion formed on the surface side of the anodized membrane body 140 in the first electrode layer 110, and the first pore electrode part 113 is a portion formed on the inner wall side of the pores P in the first electrode layer 110. The first surface electrode part 111 is formed entirely along the surface of the anodized membrane body 140. The first pore electrode part 113 is formed along the inner wall of the pores P.

The first electrode layer 110 may be composed of a metal film made of a first metal, a metal oxide film containing the first metal, a metal nitride film containing the first metal, a metal oxynitride film containing the first metal, or a combination thereof. The first metal may be Ti, Co, Nb, or Sn. In exemplary embodiments, the first electrode layer 110 may include Ti, Ti oxide, Ti nitride, Ti oxynitride, Co, Co oxide, Co nitride, Co oxynitride, Nb, Nb oxide, Nb nitride, Nb oxynitride, Sn, Sn oxide, Sn nitride, Sn oxynitride, or a combination thereof. For example, the first electrode layer 110 may be composed of TiN, CoN, NbN, SnO₂, or a combination thereof.

The dielectric layer 120 comprises a surface dielectric part 121 formed on the first surface electrode part 111 and a pore dielectric part 123 formed on the first pore electrode part 113. The surface dielectric part 121 is a portion formed on the surface side of the anodized membrane body 140 in the dielectric layer 120, and the pore dielectric part 123 is a portion formed on the inner wall side of the pores P in the dielectric layer 120. The surface dielectric part 121 is formed along the surface of the first surface electrode part 111, and the pore dielectric part 123 is formed along the surface of the first pore electrode part 113.

The dielectric layer 120 may be composed of a metal oxide film containing a second metal. The second metal may be Hf, Zr, Nb, Ce, or Ti. In exemplary embodiments, the dielectric layer 120 may be composed of Al₂O₃, ZrO₂, HfO₂, Nb₂O₅, CeO₂, or TiO₂.

The second electrode layer 130 comprises a second surface electrode part 131 formed on the surface dielectric part 121 and a second pore electrode part 133 formed on the pore dielectric part 123. The second surface electrode part 131 is a portion formed on the surface side of the anodized membrane body 140 in the second electrode layer 130, and the second pore electrode part 133 is a portion formed on the inner wall side of the pores P in the second electrode layer 130. The second surface electrode part 131 is formed along the surface of the surface dielectric part 121, and the second pore electrode part 133 is formed along the surface of the pore dielectric part 123.

The second electrode layer 130 may be composed of a metal film made of a first metal, a metal oxide film containing the first metal, a metal nitride film containing the first metal, a metal oxynitride film containing the first metal, or a combination thereof. The first metal may be Ti, Co, Nb, or Sn. In exemplary embodiments, the second electrode layer 130 may include Ti, Ti oxide, Ti nitride, Ti oxynitride, Co, Co oxide, Co nitride, Co oxynitride, Nb, Nb oxide, Nb nitride, Nb oxynitride, Sn, Sn oxide, Sn nitride, Sn oxynitride, or a combination thereof. For example, the second electrode layer 130 may be composed of TiN, CoN, NbN, SnO₂, or a combination thereof.

The capacitor component 100 according to the invention forms the structure of the capacitor through the first surface electrode part 111, the surface dielectric part 121, and the second surface electrode part 131 provided on the surface side of the anodized membrane body 140, and additionally forms the structure of another capacitor through the configuration of the first pore electrode part 113, the pore dielectric part 123, and the second pore electrode part 133 provided on the inner side of the pores P, thereby significantly improving the capacitance per unit volume.

Meanwhile, the first pore electrode part 113 is formed only on a portion of the inner wall of the pores P. In other words, the first pore electrode part 113 does not cover the entire inner wall of the pores P but only a portion thereof. More specifically, the portion of the inner wall of the pores P not covered by the first pore electrode part 113 is the central part of the inner wall of the pores P.

The pore dielectric part 123 is formed only on a portion of the inner wall of the first pore electrode part 113. In other words, the pore dielectric part 123 does not cover the entire inner wall of the first pore electrode part 113 but only a portion thereof.

The second pore electrode part 133 is formed only on a portion of the inner wall of the pore dielectric part 123. In other words, the second pore electrode part 133 does not cover the entire inner wall of the pore dielectric part 123 but only a portion thereof.

Inside the pores P, the depth of the pore dielectric part 123 is shallower than the depth of the first pore electrode part 113 and deeper than the depth of the second pore electrode part 133.

Referring to FIG. 2, the first electrode layer 110 comprises a first upper electrode layer 110a and a first lower electrode layer 11b.

The first upper electrode layer 110a comprises a first upper surface electrode part 111a formed on the upper surface of the anodized membrane body 140 and a first upper pore electrode part 113a formed on a portion of the upper inner wall of the pores P.

The first lower electrode layer 110b comprises a first lower surface electrode part 111b formed on a lower surface of the anodized membrane body 140 and a first lower pore electrode part 113b formed on a portion of a lower inner wall of the pores P.

The dielectric layer 120 comprises an upper dielectric layer 120a and a lower dielectric layer 120b.

The upper dielectric layer 120a comprises an upper surface dielectric part 121a formed on the first upper surface electrode part 111a and an upper pore dielectric part 123a formed on the first upper pore electrode part 113a.

The lower dielectric layer 120b comprises a lower surface dielectric part 121b formed on the first lower surface electrode part 111b and a lower pore dielectric part 123b formed on the first lower pore electrode part 113b.

The second electrode layer 130 comprises a second upper electrode layer 130a and a second lower electrode layer 130b.

The second upper electrode layer 130a comprises a second upper surface electrode part 131a formed on the upper surface dielectric part 121a and a second upper pore electrode part 133a formed on the upper pore dielectric part 123a.

The second lower electrode layer 130b comprises a second lower surface electrode part 131b formed on the lower surface dielectric part 121b and a second lower pore electrode part 133b formed on the lower pore dielectric part 123b.

The first upper pore electrode part 113a and the first lower pore electrode part 113b are spaced apart from each other.

The upper pore dielectric part 123a and the lower pore dielectric part 123b are spaced apart from each other.

The second upper pore electrode part 133a and the second lower pore electrode part 133b are spaced apart from each other.

On the upper side of the anodized membrane body 140, a first upper electrode layer 110a, an upper dielectric layer 120a, and a second upper electrode layer 130a are provided, and on the lower side, a first lower electrode layer 110b, a lower dielectric layer 120b, and a second lower electrode layer 130b are provided, thereby forming two capacitor structures on both sides of the anodized membrane body 140. These two capacitor structures can be connected in series or in parallel depending on the method of connecting the terminals. When a first terminal (not shown) connects the first upper electrode layer 110a and the first lower electrode layer 110b to each other, and a second terminal (not shown) connects the second upper electrode layer 130a and the second lower electrode layer 130b to each other, the two capacitor structures are connected in parallel. On the other hand, when the first terminal (not shown) is connected to either the first upper electrode layer 110a or the second upper electrode layer 130a, and the second terminal (not shown) is connected to either the first lower electrode layer 110b or the second lower electrode layer 130b, and the remaining one of the first upper electrode layer 110a and the second upper electrode layer 130a is connected to the remaining one of the first lower electrode layer 110b and the second lower electrode layer 130b, the two capacitor structures are connected in series.

Hereinafter, with reference to FIGS. 3 to 4D, a method of manufacturing the capacitor component 100 according to a preferred first embodiment of the present invention will be described. Through the description of the following manufacturing method, the configuration of the capacitor component 100 according to the first embodiment can become clearer.

The method of manufacturing the capacitor component 100 according to the first embodiment comprises (i) preparing an anodized membrane body 140, (ii) forming a first electrode layer 110 on the surface and pores P of the anodized membrane body 140, (iii) forming a dielectric layer 120 on the surface of the first electrode layer 110, and (iv) forming a second electrode layer 130 on the surface of the dielectric layer 120.

First, the step of (i) preparing the anodized membrane body 140 is performed.

FIG. 3 is a perspective view of the anodized membrane body 140, and FIG. 4A is a cross-sectional view of the anodized membrane body 140.

The anodized membrane body 140 refers to a membrane formed by anodizing a base metal M, and the pores P refer to holes formed during the process of forming the anodized membrane by anodizing the base metal M. For example, when the base metal M is aluminum Al or an aluminum alloy, anodizing the base metal M forms an anodized membrane of aluminum oxide Al₂O₃ material on the surface of the base metal M. However, the base metal M is not limited thereto and may include Ta, Nb, Ti, Zr, Hf, Zn, W, Sb, or alloys thereof. The anodized membrane thus formed is divided into a barrier layer in which pores P are not formed vertically inside and a porous layer in which pores P are formed inside.

After anodizing, when the base metal M is removed, only the anodized membrane body 140 of aluminum oxide Al₂O₃ material remains. Additionally, the barrier layer is removed so that both the upper and lower parts of the pores P are open. The pores P have a length of 1 μm to 200 μm and a diameter of 10 nm to 1 μm. The pitch between adjacent pores P has a distance of 20 nm to 200 nm.

In the present invention, since the pores P of the anodized membrane body 140 are used, a separate process for forming through-holes is unnecessary. The anodized membrane has a thermal expansion coefficient of 2-3 ppm/° C. As a result, even in high-temperature environments, thermal deformation due to temperature is minimal.

Next, the step of (ii) forming the first electrode layer 110 on the surface and pores P of the anodized membrane body 140 is performed.

Referring to FIG. 4B, the first electrode layer 110 is formed on the anodized membrane body 140. The first electrode layer 110 can be formed through a deposition process (CVD, PVD, ALD). The first electrode layer 110 can be formed with a thickness of 1 nm to 100 nm.

The first electrode layer 110 comprises a first surface electrode part 111 formed on the surface of the anodized membrane body 140 and a first pore electrode part 113 formed on the inner wall of the pores P. The first pore electrode part 113 is formed only on a portion of the inner wall of the pores P.

Next, the step of (iii) forming the dielectric layer 120 on the surface of the first electrode layer 110 is performed.

Referring to FIG. 4C, the dielectric layer 120 is formed on the surface of the first electrode layer 110. The dielectric layer 120 can be formed through a deposition process (CVD, PVD, ALD). The dielectric layer 120 can be formed with a thickness of 1 nm to 100 nm.

The dielectric layer 120 comprises a surface dielectric part 121 formed on the first surface electrode part 111 and a pore dielectric part 123 formed on the first pore electrode part 113. The pore dielectric part 123 is formed only on a portion of the inner wall of the first pore electrode part 113. Therefore, the depth of the pore dielectric part 123 is shallower than the depth of the first pore electrode part 113.

Next, the step of (iv) forming the second electrode layer 130 on the surface of the dielectric layer 120 is performed.

Referring to FIG. 4D, the second electrode layer 130 is formed on the surface of the dielectric layer 120. The second electrode layer 130 can be formed through a deposition process (CVD, PVD, ALD). The second electrode layer 130 can be formed with a thickness of 1 nm to 100 nm.

The second electrode layer 130 comprises a second surface electrode part 131 formed on the surface dielectric part 121 and a second pore electrode part 133 formed on the pore dielectric part 123. The second pore electrode part 133 is formed only on a portion of the inner wall of the pore dielectric part 123. Therefore, the depth of the second pore electrode part 133 is shallower than the depth of the pore dielectric part 123.

Through the above series of processes, the manufacturing of the capacitor component 100 is completed. However, even after forming the second electrode layer 130, the pores P may have space. If the pores P have space after forming the second electrode layer 130, the space can provide room for thermal expansion of the first electrode layer 110, the dielectric layer 120, and the second electrode layer 130, and the capacitor component 100 can also be cooled by air cooling through the space. Meanwhile, functional materials can also be filled in the space of the pores P after forming the second electrode layer 130. Here, the functional material may be a metal material or an insulating material.

### Capacitor Component 100 According to the Second Embodiment

Next, the second embodiment of the present invention will be described. However, the embodiments described below will focus on characteristic components compared to the first embodiment, and descriptions of components that are the same as or similar to those of the first embodiment will be omitted.

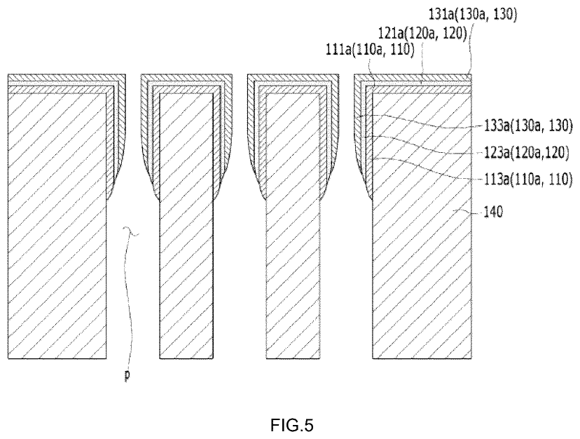

FIG. 5 is a cross-sectional view of the capacitor component 100 according to a preferred second embodiment of the present invention.

The capacitor component 100 according to the second embodiment differs from the configuration of the first embodiment, in which the first electrode layer 110, the dielectric layer 120, and the second electrode layer 130 are formed on both sides of the anodized membrane body 140, in that the first electrode layer 110, the dielectric layer 120, and the second electrode layer 130 are formed only on one side of the anodized membrane body 140, while the remaining configuration is the same.

### Capacitor Component 100 According to the Third Embodiment

Next, the third embodiment of the present invention will be described. However, the embodiments described below will focus on characteristic components compared to the first embodiment, and descriptions of components that are the same as or similar to those of the first embodiment will be omitted.

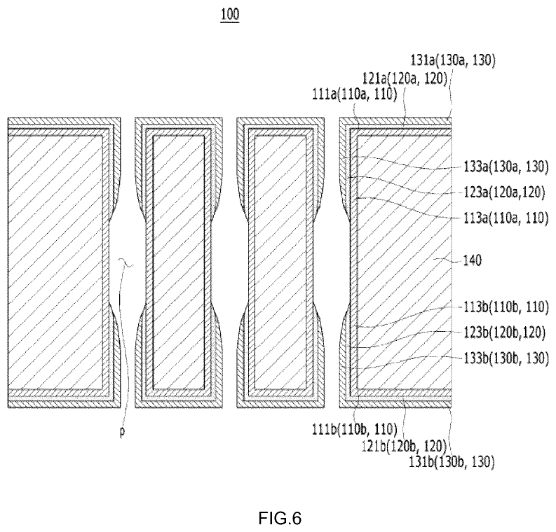

FIG. 6 is a cross-sectional view of the capacitor component 100 according to a preferred third embodiment of the present invention.

The capacitor component 100 according to the third embodiment differs from the configuration of the first embodiment, in which the first upper pore electrode part 113a and the first lower pore electrode part 113b are spaced apart from each other, in that the first upper pore electrode part 113a and the first lower pore electrode part 113b are connected to each other, while the remaining configuration is the same.

The first upper electrode layer 110a comprises a first upper surface electrode part 111a formed on the upper surface of the anodized membrane body 140 and a first upper pore electrode part 113a formed on a portion of the upper inner wall of the pores P. The first lower electrode layer 110b comprises a first lower surface electrode part 111b formed on the lower surface of the anodized membrane body 140 and a first lower pore electrode part 113b formed on a portion of the lower inner wall of the pores P.

The dielectric layer 120 comprises an upper dielectric layer 120a and a lower dielectric layer 120b. The upper dielectric layer 120a comprises an upper surface dielectric part 121a formed on the first upper surface electrode part 111a and an upper pore dielectric part 123a formed on the first upper pore electrode part 113a. The lower dielectric layer 120b comprises a lower surface dielectric part 121b formed on the first lower surface electrode part 111b and a lower pore dielectric part 123b formed on the first lower pore electrode part 113b.

The second electrode layer 130 comprises a second upper electrode layer 130a and a second lower electrode layer 130b. The second upper electrode layer 130a comprises a second upper surface electrode part 131a formed on the upper surface dielectric part 121a and a second upper pore electrode part 133a formed on the upper pore dielectric part 123a. The second lower electrode layer 130b comprises a second lower surface electrode part 131b formed on the lower surface dielectric part 121b and a second lower pore electrode part 133b formed on the lower pore dielectric part 123b.

The first upper pore electrode part 113a and the first lower pore electrode part 113b are connected to each other. The first upper pore electrode part 113 a and the first lower pore electrode part 113b entirely cover the inner wall of the pores P.

The upper pore dielectric part 123a and the lower pore dielectric part 123b are spaced apart from each other, and the second upper pore electrode part 133a and the second lower pore electrode part 133b are spaced apart from each other.

### Capacitor Component 100 According to the Fourth Embodiment

Next, the fourth embodiment according to the present invention will be described. However, the embodiments described below will focus on characteristic components compared to the first embodiment, and descriptions of components identical or similar to those in the first embodiment will be omitted.

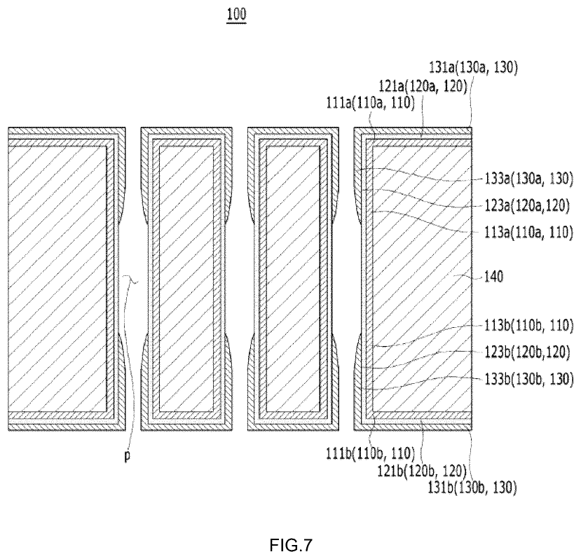

FIG. 7 is a cross-sectional view of a capacitor component 100 according to a preferred fourth embodiment of the present invention.

The capacitor component 100 according to the fourth embodiment differs from the configuration of the first embodiment, in which the first upper pore electrode part 113a and the first lower pore electrode part 113b are spaced apart, and the upper pore dielectric part 123a and the lower pore dielectric part 123b are spaced apart. In the fourth embodiment, the first upper pore electrode part 113a and the first lower pore electrode part 113b are connected to each other, and the upper pore dielectric part 123a and the lower pore dielectric part 123b are connected to each other, while the remaining configuration is the same.

The first upper electrode layer 110a comprises a first upper surface electrode part 111a formed on the upper surface of the anodized membrane body 140 and a first upper pore electrode part 113a formed on a portion of the upper inner wall of the pores P. The first lower electrode layer 110b comprises a first lower surface electrode part 111b formed on the lower surface of the anodized membrane body 140 and a first lower pore electrode part 113b formed on a portion of the lower inner wall of the pores P.

The dielectric layer 120 comprises an upper dielectric layer 120a and a lower dielectric layer 120b. The upper dielectric layer 120a comprises an upper surface dielectric part 121a formed on the first upper surface electrode part 111a and an upper pore dielectric part 123a formed on the first upper pore electrode part 113a. The lower dielectric layer 120b comprises a lower surface dielectric part 121b formed on the first lower surface electrode part 111b and a lower pore dielectric part 123b formed on the first lower pore electrode part 113b.

The second electrode layer 130 comprises a second upper electrode layer 130a and a second lower electrode layer 130b. The second upper electrode layer 130a comprises a second upper surface electrode part 131a formed on the upper surface dielectric part 121a and a second upper pore electrode part 133a formed on the upper pore dielectric part 123a. The second lower electrode layer 130b comprises a second lower surface electrode part 131b formed on the lower surface dielectric part 121b and a second lower pore electrode part 133b formed on the lower pore dielectric part 123b.

The first upper pore electrode part 113a and the first lower pore electrode part 113b are connected to each other. The first upper pore electrode part 113a and the first lower pore electrode part 113b entirely cover the inner wall of the pores P.

The upper pore dielectric part 123a and the lower pore dielectric part 123b are connected to each other. The upper pore dielectric part 123a and the lower pore dielectric part 123b entirely cover the first upper pore electrode part 113a and the first lower pore electrode part 113b.

The second upper pore electrode part 133a and the second lower pore electrode part 133b are spaced apart from each other.

### Integrated Circuit Chip Package 1000

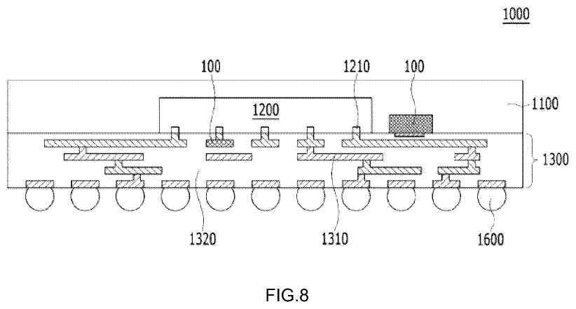

FIG. 8 is a cross-sectional view of an integrated circuit chip package 1000 in which the capacitor component 100 according to a preferred embodiment of the present invention is embedded.

The integrated circuit chip package 1000 according to a preferred embodiment of the present invention comprises a package substrate 1300, a semiconductor chip 1200 mounted on the package substrate 1300, a molding part 1100 protecting the semiconductor chip 1200, and a capacitor component 100 provided inside or on the package substrate 1300.

The semiconductor chip 1200 may be a logic chip comprising a logic circuit. The logic chip may be a controller controlling memory chips. In other exemplary embodiments, the semiconductor chip 1200 may be a memory chip. The memory chip may comprise various types of memory circuits. The memory circuit may be composed of DRAM (Dynamic Random Access Memory), SRAM (Static RAM), FRAM (Ferromagnetic RAM), PRAM (Phase Change RAM), MRAM (Magnetic RAM), RRAM (Resistive RAM), ROM (Read Only Memory), MROM (Mask ROM), PROM (Programmable ROM), EPROM (Erasable ROM), EEPROM (Electrically Erasable ROM), or combinations thereof.

The package substrate 1300 may comprise a plurality of wiring layers 1310 configured to be electrically connected to a plurality of chip pads 1210 included in the semiconductor chip 1200, and an insulating film 1320 selectively insulating adjacent wiring layers 1310 among the plurality of wiring layers 1310. The plurality of wiring layers 1310 included in the package substrate 1300 may comprise Al, Cu, Sn, Ni, Au, Pt, or alloys thereof. A plurality of external connection members 1600 may be connected to the package substrate 1300.

The package substrate 1300 comprises the capacitor component 100. The capacitor component 100 may be configured to be electrically connectable to some of the chip pads 1210 included in the semiconductor chip 1200 or to some of the wiring layers 1310 included in the package substrate 1300. The capacitor component 100 may comprise any one selected from the capacitor components 100 according to the first to third embodiments, or capacitor components 100 having various structures modified and changed within the scope of the technical idea of the present invention.

As described above, although the preferred embodiments of the present invention have been described with reference to the accompanying drawings, those skilled in the art may variously modify or change the present invention without departing from the spirit and scope of the invention as set forth in the following claims.

### DESCRIPTION OF THE REFERENCE NUMERALS IN THE DRAWINGS

100: Capacitor component
110: First electrode layer
120: Dielectric layer
130: Second electrode layer
140: Anodized membrane body

1. A capacitor component comprising:
an anodized membrane body having a plurality of pores;
a first electrode layer comprising a first surface electrode part formed on a surface of the anodized membrane body and a first pore electrode part formed on an inner wall of the pores;
a dielectric layer comprising a surface dielectric part formed on the first surface electrode part and a pore dielectric part formed on the first pore electrode part; and
a second electrode layer comprising a second surface electrode part formed on the surface dielectric part and a second pore electrode part formed on the pore dielectric part.

2. The capacitor component of claim 1, wherein
the first pore electrode part is formed only on a portion of the inner wall of the pores.

3. The capacitor component of claim 1, wherein
the first pore electrode part is formed on the entire inner wall of the pores.

4. The capacitor component of claim 1, wherein
inside the pores, a depth of the pore dielectric part is shallower than a depth of the first pore electrode part and deeper than a depth of the second pore electrode part.

5. A capacitor component comprising:
an anodized membrane body having a plurality of pores;
a first upper electrode layer comprising a first upper surface electrode part formed on an upper surface of the anodized membrane body and a first upper pore electrode part formed on a portion of an upper inner wall of the pores;
an upper dielectric layer comprising an upper surface dielectric part formed on the first upper surface electrode part and an upper pore dielectric part formed on the first upper pore electrode part;
a second upper electrode layer comprising a second upper surface electrode part formed on the upper surface dielectric part and a second upper pore electrode part formed on the upper pore dielectric part;
a first lower electrode layer comprising a first lower surface electrode part formed on a lower surface of the anodized membrane body and a first lower pore electrode part formed on a portion of a lower inner wall of the pores;
a lower dielectric layer comprising a lower surface dielectric part formed on the first lower surface electrode part and a lower pore dielectric part formed on the first lower pore electrode part; and
a second lower electrode layer comprising a second lower surface electrode part formed on the lower surface dielectric part and a second lower pore electrode part formed on the lower pore dielectric part.

6. The capacitor component of claim 5, wherein
the first upper pore electrode part and the first lower pore electrode part are spaced apart from each other.

7. The capacitor component of claim 5, wherein
the upper pore dielectric part and the lower pore dielectric part are spaced apart from each other.

8. The capacitor component of claim 5, wherein
the second upper pore electrode part and the second lower pore electrode part are spaced apart from each other.

9. An integrated circuit chip package comprising:
a package substrate;
a semiconductor chip mounted on the package substrate;
a molding part protecting the semiconductor chip; and
a capacitor component provided inside or on the package substrate,
wherein the capacitor component comprises:
an anodized membrane body having a plurality of pores;
a first electrode layer comprising a first surface electrode part formed on a surface of the anodized membrane body and a first pore electrode part formed on an inner wall of the pores;
a dielectric layer comprising a surface dielectric part formed on the first surface electrode part and a pore dielectric part formed on the first pore electrode part; and
a second electrode layer comprising a second surface electrode part formed on the surface dielectric part and a second pore electrode part formed on the pore dielectric part.
